(19) United States
(12) Patent Application Publication
(10) Pub. No.: US 2017/0175262 A1
(43) Pub. Date: Jun. 22, 2017

(54) EPITAXIAL GROWTH APPARATUS, EPITAXIAL GROWTH METHOD, AND MANUFACTURING METHOD OF SEMICONDUCTOR ELEMENT

(71) Applicant: Fuji Electric Co., Ltd., Kanagawa (JP)

(72) Inventor: Yasuyuki KAWADA, Ibaraki (JP)

(73) Assignee: Fuji Electric Co., Ltd., Kanagawa (JP)

(21) Appl. No.: 15/346,031

(22) Filed: Nov. 8, 2016

(30) Foreign Application Priority Data
Dec. 16, 2015 (JP) 2015-244770

(51) Int. Cl. C23C 16/32; C23C 16/458; C23C 16/52; H01L 21/02; H01L 21/04

(52) U.S. Cl. CPC C23C 16/325; H01L 21/02529; H01L 21/02576; H01L 21/0262; H01L 21/046; C23C 16/52; C23C 16/458

(57) ABSTRACT

An epitaxial growth apparatus includes: a reaction vessel where a semiconductor film made of silicon carbide is epitaxially grown on a substrate; a tray having a top surface, a bottom surface, and an indentation in the top surface that houses the substrate, a thickness of the tray near a center of the indentation being greater than a thickness of the tray near an edge of the indentation as measured from a bottom of the indentation to the bottom surface of the tray; and a support plate inside the reaction vessel that mounts the tray thereon so as to thermally contact the tray, thereby heating the tray.

### BACKGROUND OF THE INVENTION

Technical Field

The present invention relates to an epitaxial growth apparatus, an epitaxial growth method that uses the epitaxial growth apparatus, and a manufacturing method of a semiconductor element that utilizes the epitaxial growth apparatus.

Background Art

When manufacturing a silicon carbide (SiC) power semiconductor element, a method is sometimes used in which a 4H—SiC film is epitaxially grown on a 4H-SiC semiconductor substrate.

At such time, in order to improve the properties of the semiconductor element and manufacture the semiconductor element at a high yield, it is necessary to control the thickness distribution of the 4H—SiC film within the plane of the substrate, control the concentration distribution of impurity elements, prevent crystal defects, prevent dislocation, prevent warping of the substrate, and the like. However, it is often difficult to manufacture an epitaxial substrate in which all of these criteria are satisfactorily met. In particular, when heat treatment is performed to promote epitaxial growth, problems occur regarding the above-mentioned criteria if the temperature distribution of the 4H—SiC substrate is uneven.

One method that has been proposed for improving this unevenness in the temperature distribution is to dispose insulating material on a portion of a susceptor of a CVD apparatus, which is an epitaxial growth apparatus, and use this insulating material to improve the temperature distribution and promote epitaxial growth by blocking a portion of the heat transmitted to the semiconductor substrate while the semiconductor substrate is disposed on the susceptor (see Patent Document 1).

However, in the invention disclosed in Patent Document 1, it is necessary to separately prepare a type of insulating material that is different from the main body of the susceptor, thus leading to a problem of increased costs.

### RELATED ART DOCUMENT

Patent Document
Patent Document 1: Japanese Patent Application Laid-Open Publication No. 2014-144880

### SUMMARY OF THE INVENTION

The present invention was designed with a focus on the above-mentioned problems, and an aim thereof is to provide an epitaxial growth apparatus and an epitaxial growth method that can epitaxially grow a high-quality silicon carbide semiconductor substrate while reducing costs, and a manufacturing method of a semiconductor element that utilizes this epitaxial growth apparatus. Accordingly, the present invention is directed to a scheme that substantially obviates one or more of the problems due to limitations and disadvantages of the related art.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides An epitaxial growth apparatus, including: a reaction vessel where a semiconductor film made of silicon carbide is epitaxially grown on a substrate; a tray having a top surface, a bottom surface, and an indentation in the top surface that houses the substrate, a thickness of the tray near a center of the indentation being greater than a thickness of the tray near an edge of the indentation as measured from a bottom of the indentation to the bottom surface of the tray; and a support plate inside the reaction vessel that mounts the tray thereon so as to thermally contact the tray, thereby heating the tray.

In another aspect, the present disclosure provides a method of epitaxial growth, including: preparing a tray having an indentation provided in a top surface of the tray, a thickness of the tray near a center of the indentation being thicker than a thickness of the tray near an edge of the indentation as measured from a bottom of the indentation to a bottom surface of the tray; housing a substrate in the indentation in the tray; placing the tray inside a reaction vessel and mounting the tray on a support plate; and increasing a temperature of the substrate by heating the substrate via the support plate and the tray so as to epitaxially grow a semiconductor film made of silicon carbide on the substrate.

In another aspect, the present disclosure provides a method of manufacturing a semiconductor element, including: preparing a tray having an indentation provided in a top surface of the tray, a thickness of the tray near a center of the indentation being thicker than a thickness of the tray near an edge of the indentation as measured from a bottom of the indentation to a bottom surface of the tray; housing a substrate in the indentation in the tray; placing the tray inside a reaction vessel and mounting the tray on a support plate; forming a first semiconductor region by increasing a temperature of the substrate by heating the substrate via the support plate and the tray so as to epitaxially grow a semiconductor film made of silicon carbide on the substrate; and forming a second semiconductor region by introducing an impurity element into a top of the first semiconductor region.

Therefore, according to an epitaxial growth apparatus, an epitaxial growth method, and a manufacturing method of a semiconductor element according to the present invention, it is possible to epitaxially grow a high-quality silicon carbide semiconductor substrate while reducing costs.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a block diagram that includes a cross-sectional view for schematically showing a general configuration of an epitaxial growth apparatus according to an embodiment of the present invention.

FIG. 2 is a cross-sectional view as seen from the direction of a line A-A in FIG. 1.

FIG. 3A is a top view of a tray according to Working Example 1 of the present invention, FIG. 3B is a cross-sectional view as seen from the direction of a line B-B in FIG. 3A, and FIG. 3C is a bottom view of the tray according to Working Example 1.

FIG. 4 is a flow chart for explaining an epitaxial growth method according to an embodiment of the present invention.

FIG. 5A is a top view of a tray according to Working Example 2 of the present invention, FIG. 5B is a cross-sectional view as seen from the direction of a line C-C in FIG. 5A, and FIG. 5C is a bottom view of the tray according to Working Example 2.

FIG. 6A is a top view of a tray according to Working Example 3 of the present invention, FIG. 6B is a cross-sectional view as seen from the direction of a line D-D in FIG. 6A, and FIG. 6C is a bottom view of the tray according to Working Example 3.

FIG. 7A is a top view of a tray according to a comparison example, FIG. 7B is a cross-sectional view along a line E-E in FIG. 7A, and FIG. 7C is a bottom view of the tray according to the comparison example.

FIG. 8 is a graph that shows the distribution of the amount of etching within a substrate plane when SiC films are hydrogen etched using the respective trays according to the comparison example and the working examples of the present invention.

FIG. 9 shows the thickness distribution when a SiC monocrystalline layer is epitaxially grown using the respective trays according to the comparison example and the working examples of the present invention.

FIG. 10 is a graph that shows a stress occurrence distribution for a film within the substrate plane when an SiC monocrystalline layer is epitaxially grown using the respective trays according to the comparison example and the working examples of the present invention.

FIG. 11A is an image that shows the interface dislocation state of a film when a SiC monocrystalline layer is epitaxially grown using the tray according to the comparison example.

FIG. 11B is an image that shows the interface dislocation state of a film when a SiC monocrystalline layer is epitaxially grown using the tray according to Working Example 1.

FIG. 11C is an image that shows the interface dislocation state of a film when a SiC monocrystalline layer is epitaxially grown using the tray according to Working Example 2.

FIGS. 12A, 12B, 12C, and 12D are cross-sectional views of steps that shows in that order the process for a manufacturing method of a semiconductor element according to an embodiment of the present invention.

FIG. 13 is a cross-sectional view for schematically explaining a general configuration of a tray according to another embodiment of the present invention.

### DETAILED DESCRIPTION OF EMBODIMENTS

Embodiments of the present invention will be described below. In the drawings mentioned below, portions that are the same or similar will be assigned the same or similar reference characters. However, it should be noted that the drawings are schematic, and that the relationships between the thicknesses and the planar dimensions, the thickness ratios of the various devices and various members, and the like, differ from reality. Therefore, specific thicknesses and dimensions should be determined based on the description below. In addition, there are portions that differ in the depicted dimensional relationships and ratios among the various drawings.

In the explanation below, the directions of “left/right” and “up/down” are simply defined for ease of explanation, and do not limit the technical ideas of the present invention. Therefore, “left/right” and “up/down” can be understood to switch with each other when the paper surface is rotated by 90 degrees, and “left” becomes “right” and “right” becomes “left” when the paper surface is rotated by 180 degrees, for example. Furthermore, in the present specification and attached drawings, regions and layers marked with an “n” or “p” respectively signify that electrons or holes are the majority carrier. A “+” or “−” attached to an “n” or “p” signifies a semiconductor region in which the impurity concentration is relatively higher or lower, respectively, than in a semiconductor region not having the “+” or “−.”

(Epitaxial Growth Apparatus)

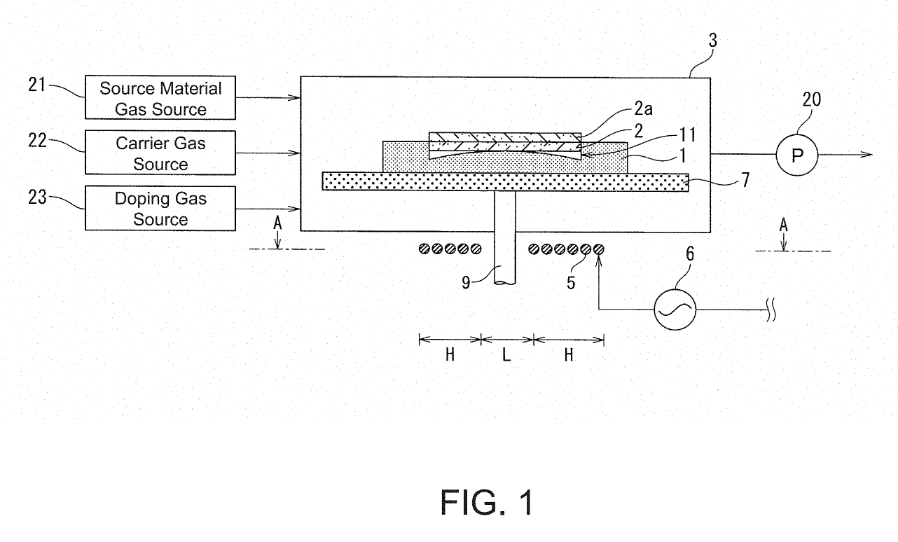

As shown in FIG. 1, an epitaxial growth apparatus according to an embodiment of the present invention includes: a reaction vessel 3 that heats a substrate 2 and epitaxially grows a semiconductor film 2a made of silicon carbide (SiC) on the substrate 2; a support plate 7 provided inside the reaction vessel 3; and a dish-shaped tray 1 disposed on the support plate 7 such that the substrate 2 rests thereon.

The tray 1 has a top surface and a bottom surface, and includes an indentation 11 that houses the substrate 2 on the top surface side. The tray 1 has a thickness distribution such that the thickness from a bottom of the indentation 11 to the bottom surface of the tray 1 is thicker in a region that contacts the center of the substrate 2 than in regions at the edges of the substrate 2. In other words, the thickness in the in-plane direction of a region of that contacts the substrate 2 in the indentation 11 is designed to take into account the distribution of the flow of heat, and the center thereof is therefore thicker than the edges. The support plate 7 is mounted so as to thermally contact the tray 1, and heats and increases the temperature of the tray 1 by transmitting heat generated within the support plate 7 toward the substrate 2.

As shown in FIG. 1, the epitaxial growth apparatus also includes: a rotational shaft 9 that supports the support plate 7 from the bottom and causes the support plate 7 to rotate; a high frequency induction coil (heater coil) 5 that is provided below the support plate 7 and uses high frequency induction heating to heat the support plate 7 and the tray 1; and a high frequency power source 6 connected to the high frequency induction coil 5.

The epitaxial growth apparatus also includes a source material gas source 21, a carrier gas source 22, and a doping gas source 23 that are connected to the reaction vessel 3 and in which source material gases, carrier gases, doping gases, and the like for epitaxially growing and forming the semiconductor film 2a on the substrate 2 are respectively stored.

The epitaxial growth apparatus also includes a vacuum pump 20 made of a rotary pump, a turbomolecular pump, a cryopump, or the like, that is connected to the reaction vessel 3 and changes the inside of the reaction vessel 3 into a vacuum state.

It is preferable that, in order to meet the definition of “epitaxial growth,” the substrate 2 be an SiC substrate that is homoepitaxially grown on the same crystal lattice as the to-be-formed SiC film. However, heteroepitaxial growth that utilizes a silicon (Si) substrate or a gallium nitride (GaN) substrate as the substrate 2 may also be used. Furthermore, when performing growth such as rheotaxial growth that utilizes an insulating substrate such as a sapphire substrate as the substrate 2, it is possible to use a broad definition for the concept of epitaxial growth.

In the description below, a specific example is used in which an n⁺4H—SiC substrate that is expected to be used as a substrate material used in a power semiconductor element is used as the substrate 2.

The reaction vessel (reactor) 3 is made of quartz tubes or the like. Inside the reaction vessel 3, a 4H—SiC substrate is mounted as the substrate 2 such that the Si surface or C surface of the SiC is inclined at a prescribed angle (an off-angle) on the support plate 7 with the tray 1 interposed therebetween. The off-angle may be set to approximately 8°, for example, but is not limited to 8° and may be set as appropriate.

The source material gas source 21, the carrier gas source 22, and the doping gas source 23 are schematically shown as gas supply sources used in film formation. A configuration of an actual epitaxial growth apparatus may differ from the example shown in FIG. 1. Various types of auxiliary devices, such as a theremostatic chamber, may be provided in accordance with the number of gas types included in the plurality of gases that will be used, for example. In addition, a plurality of gas introduction valves may be provided so as to correspond to the respective gas sources that provide the plurality of gases. In addition, corresponding piping groups may be respectively provided between the respective gas sources and the reaction vessel 3, forming a plurality of piping systems.

The support plate (susceptor) 7 is made of carbon c or the like that has been coated using crystals made of SiC, tantalum carbide (TaC), or the like. The susceptor 7 generates heat via high frequency induction heating and heats the substrate 2 via the tray 1. Additional members, such as an insulating plate, may be provided on the bottom side of the susceptor 7.

One end face of the rotational shaft 9 is fixed and attached to the bottom surface (rear surface) of the susceptor 7 constituting the support plate 7 such that the susceptor 7 is concentric with the shaft center of the rotational shaft 9. The other end of the rotational shaft 9 is attached to a rotational drive device (not shown). The susceptor 7 rotates (autorotation) in coordination with the rotation of the rotational shaft 9 about the shaft center.

A light-plate shielding plate (not shown) and cooling pipes (not shown) that pass cooling water, which cools the light-shielding plate, in the interior thereof are provided on the high frequency induction coil 5. The high frequency induction coil 5 will be hereafter abbreviated as “the RF coil 5.”

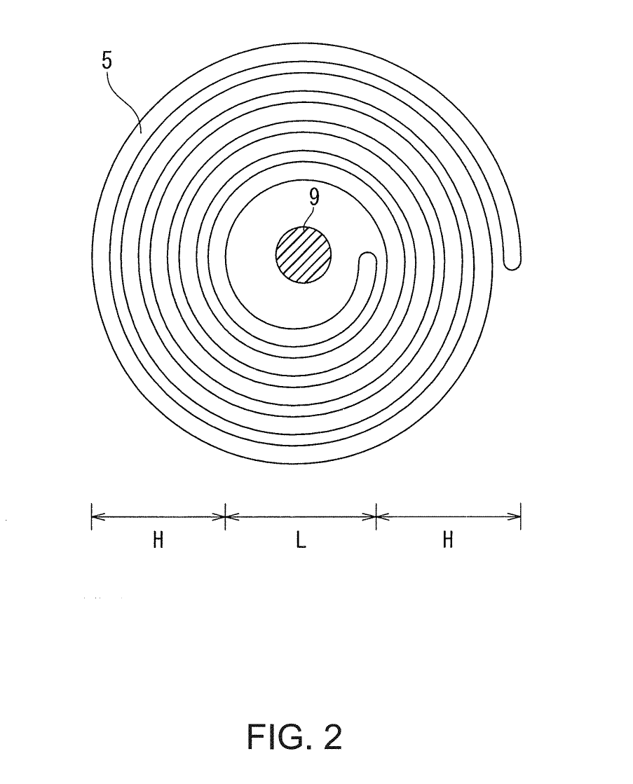

As shown in the cross-sectional view of FIG. 2, one end of the RF coil 5 is disposed near the outer peripheral surface of the rotational shaft 9, and the RF coil 5 forms a coil shape that extends outward in a horizontal plane parallel to the main surface of the substrate 2 with the one end of the RF coil 5 functioning as the starting point of the coil and the shaft center of the rotational shaft 9 functioning as the center of a spiral. The other end of the RF coil 5, which is the end point of the coil, is disposed on roughly the same straight line as the location of the starting point of the coil.

The coil shape of the RF coil 5, when viewed from above, is provided in a ring-shaped region that excludes the central rotational shaft 9 and a portion of the region surrounding the rotational shaft 9. In the embodiment of the present invention, the susceptor 7 is disposed mainly above the rotational shaft 9. In an apparatus such as that shown in FIG. 1, a circular low RF input region L in the center of the susceptor 7 and a high RF input region H, which is located in a ring-shaped section at the edges of the susceptor 7 and is located above the RF coil 5 at the periphery of the low RF input region L, are defined as two thermal divisions. In other words, in the low RF input region L, the amount of heat conducted from the RF coil 5 via the rotational shaft 9 is smaller than in the high RF input region H, and the temperature is therefore less likely to increase.

Then, as a result of the distribution of RF energy that provides primary heating to the tray 1 and secondary heating provided by the high RF input region H and the low RF input region L of the susceptor 7, the center of the tray 1 becomes a low heat energy region and a periphery of the low heat energy region of the tray 1 becomes a high heat energy region. Therefore, in a configuration that includes a rotational shaft 9 such as that shown in FIG. 1, the center of the tray 1 becomes a region in which the temperature is less likely to increase.

(Structure of the Tray)

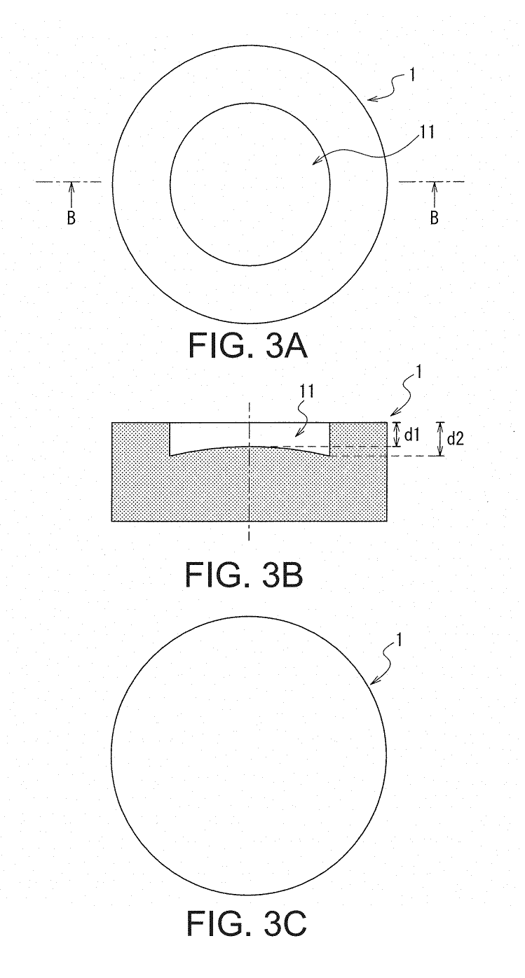

As shown in FIGS. 3A to 3C, the planar shape of the tray 1 as seen from above is a substantially circular plate-like, and the tray 1 is made of C, for example. As shown in the top view in FIG. 3A and the cross-sectional view in FIG. 3B, an indentation (counterbore) 11 that has substantially the same diameter as the diameter of the substrate 2 is formed in the center of the top surface of the tray 1 such that the depth is not uniform. In the working examples described hereafter, the planar shape of the tray 1 is circular. In cases such as when a horizontal CVD apparatus is used, however, the planar shape of the tray 1 may be a square plate-like shape.

As shown in FIG. 3B, the bottom of the indentation 11 is a curved surface that has a protrusion that partially protrudes upward with respect to the bottom surface of the tray 1. In other words, a depth d2 at an edge of the bottom of the indentation 11 is the deepest depth, and the bottom of the indentation 11 is designed to protrude upward so as to gradually rise up higher moving in the left-right direction from the edges toward the center, thereby meaning that a depth d1 at the center is the most shallow depth.

When the substrate 2 is a three inch (approximately 77 mm) wafer, for example, the depth d1 at the center of the indentation 11 can be configured so as to be approximately 0.4 mm to 3 mm.

As shown in the bottom view of FIG. 3C, the bottom surface of the tray 1 that contacts the susceptor 7 is flat, and no particular treatment is performed on this bottom surface. For the tray 1 shown in FIGS. 3A to 3C, the bottom of the indentation 11 is formed as a protrusion in which the central region is thicker and protrudes further upward compared to the edge regions. In addition, the bottom of the indentation 11 is configured such that when the substrate 2 is mounted in the indentation 11, the bottom of the indentation 11 partially contacts the substrate 2 in the central region and gaps are formed between the substrate 2 and the tray 1 in the edge regions.

Thus, in the edge regions, the distance gradually increases such that the bottom of the indentation 11 does not contact the substrate 2, and heat is prevented from being conducted and radiated from the high RF input region H and the high heat energy region. Meanwhile, in the central region, a contact region with the substrate 2 is sufficiently ensured; thus, heat conducted from the low RF input region L and the low heat energy region reliably flows to the substrate 2. The contact area of the substrate 2 and the central region of the indentation 11 of the tray 1 and the radius of curvature of the contacted curved surface of the tray 1 are set so as to take into account the temperature difference (the temperature distribution within a horizontal plane parallel to the substrate 2) with the edge regions.

In this manner, by having the shape of the indentation 11 in which the substrate 2 is mounted characteristically change along the horizontal direction in the in-plane direction of the substrate 2, the tray 1 aims to prevent unevenness in the overall flow of heat (heat flow) to the substrate 2, promote epitaxial growth by appropriately controlling the temperature distribution within the plane of the substrate 2, and improve the thickness distribution of the 4H—SiC film.

(Epitaxial Growth Method)

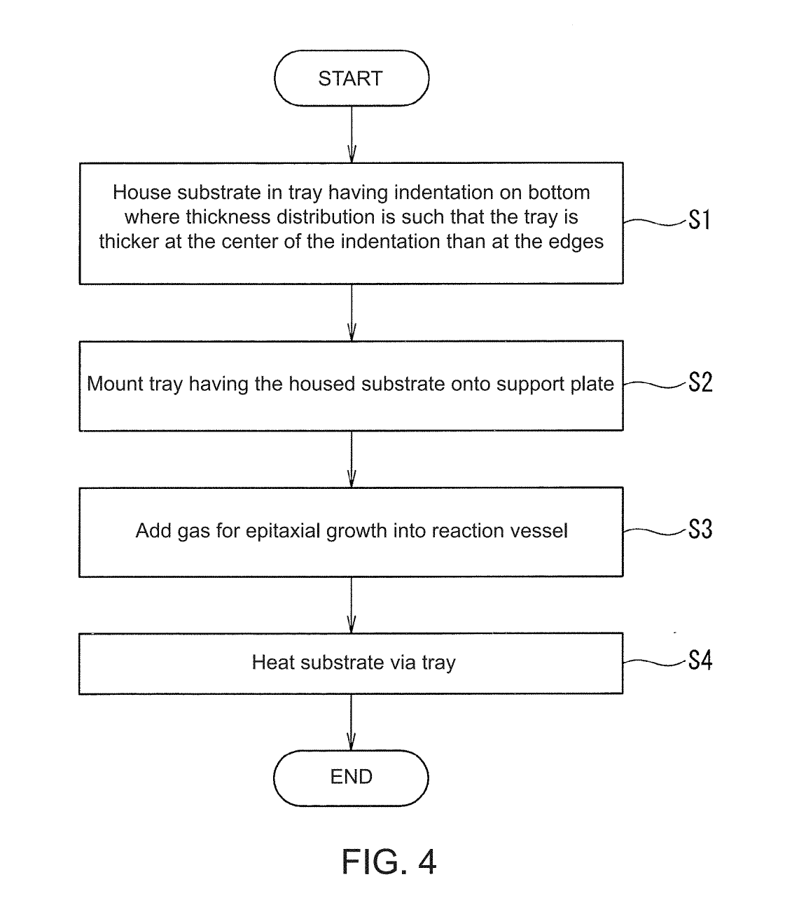

Next, an example of a method of manufacturing an epitaxial substrate via chemical vapor deposition (CVD) that utilizes the epitaxial growth apparatus shown in FIG. 1 will be described using the flow chart in FIG. 4.

First, during Step S1 in FIG. 4, a tray 1 is prepared in which an indentation 11 has been formed such that, between the bottom of the indentation 11 and the bottom surface of the tray 1, the thickness of the tray 1 in the center is larger than the thickness at the edges. A 4H-SiC substrate 2 is then housed within the indentation 11 in the tray 1.

Next, during Step S2, the tray 1, which has been placed inside the reaction vessel 3 of the epitaxial growth apparatus shown in FIG. 1 and which houses the substrate 2 above a susceptor 7, is mounted so as to be set in a prescribed place, thereby fixing the location of the tray 1.

Next, monosilane (SiH₄) gas and propane (C₃H₈) gas are prepared as the source material gases in the source material gas source 21 shown in FIG. 1. Silicon tetrachloride (SiCl₄), disilane (SiH₆), trichlorosilane (SiHCl₃), or the like may be used instead of SiH₄, and methane (CH₄), ethane (C₂H₆), acetylene (C₂H₂), or the like may be used instead of C₃H₈.

In addition, hydrogen (H₂) gas is prepared as the carrier gas in the carrier gas source 22, and nitrogen (N₂) gas, trimethyl aluminum (C₆H₁₈Al₂; TMA), or the like is prepared in the doping gas source 23 as the gas for doping impurity elements.

Next, during Step S3 in FIG. 4, the source material gases, carrier gas, and doping gas are respectively appropriately added inside the reaction vessel 3 of the epitaxial growth apparatus.

Next, during Step S4 in FIG. 4, the susceptor 7 is heated via the RF coil 5, the tray 1 on the susceptor 7 is heated using secondary heating that consists mainly of conduction and radiation from the susceptor 7, the substrate 2 is heated via the tray 1, and a semiconductor film 2a that is a 4H—SiC film is epitaxially grown on the substrate 2. If the 4H—SiC film is formed at a desired thickness on the top surface of the substrate 2, it is possible to manufacture an epitaxial substrate in which the thickness distribution has been controlled.

According to an epitaxial growth apparatus of an embodiment of the present invention, by additionally treating the front surface (top surface), rear surface (bottom surface), or both the front and rear surfaces of the tray 1, the thickness of the center of the tray 1 from the front surface toward the rear surface becomes thicker, and the thickness toward the outside in the radial direction becomes thinner; thus, the distance between the tray 1 and the substrate 2 is caused to change along the radial direction. As a result, the propagation of heat from the RF coil 5 to the substrate 2 via the tray 1, or in other words, the distribution of heat flow and the distribution of RF power, is changed along the radial direction and the temperature distribution of the SiC substrate is controlled.

As a result, the amount of the source material gases deposited on the substrate 2 during CVD and the amount of etching by H₂, the carrier gas, is controlled, and the thickness distribution is controlled such that the thickness becomes uniform. Specifically, the substrate 2 promotes epitaxial growth such that the thickness of the film is thinner in a high temperature section compared to current devices, and such that the thickness of the film is thicker in a low temperature section compared to current devices, thereby controlling the distribution of the thickness of the epitaxially grown film that was dependent on the high temperature section and the low temperature section.

In addition, tensile stress generated at the edges of the substrate 2 is reduced by suppressing unevenness in the temperature distribution to the fullest extent possible, and warping of the substrate 2 is reduced by decreasing the stress on the substrate 2 as a whole. As a result, it is possible to reduce the frequency of occurrence of interface dislocation, slip lines (slip dislocations), and the like that occur most frequently at the edges of the substrate 2.

According to an epitaxial growth method of an embodiment of the present invention, it is not necessary to control temperature by embedding insulating material, which is of a different material than the susceptor 7, between the susceptor 7 and the substrate 2, and it is possible to form the tray 1 using a single material; thus, it is possible to easily carry out treatment while reducing costs, and it is not necessary to use an insulating material.

(Other Embodiments of the Tray)

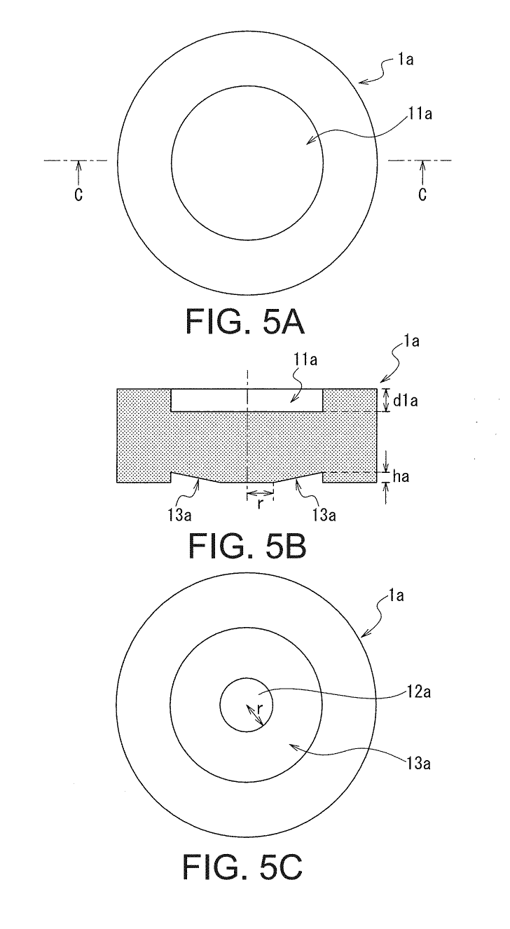

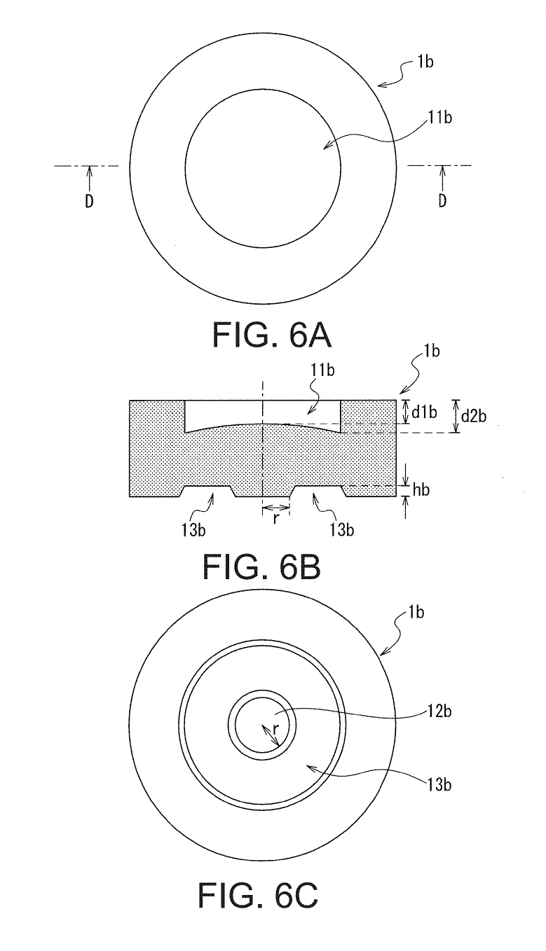

In addition, a tray used in an epitaxial growth apparatus of an embodiment of the present invention may have a configuration other than that shown in FIGS. 3A to 3C, and it possible to configure the tray in the shapes shown in FIGS. 5A to 6C.

As shown in FIGS. 5A to 5C the planar shape of the tray as seen from above may be a substantially circular plate-like shape, and the tray may be a tray 1a in which an indentation 11a that has a diameter that is substantially the same as the diameter of the substrate 2 is formed in the center of the front surface on which the substrate 2 rests, for example. As shown in the top view of FIG. 5A and the cross-sectional view of FIG. 5B, the planar shape of the indentation 11a in the tray 1a is substantially circular, and the entire bottom of the indentation 11a is flat. A depth d1a at the center of the indentation 11a can be configured so as to be approximately 0.4 mm to 3 mm, the same as for the tray 1 shown in FIGS. 3A to 3C.

In addition, as shown in the bottom view of FIG. 5C, a circular flat section 12a is provided on the rear surface side of the tray 1a in a region that extends outward from the center to a radius r. The contact area of the susceptor 7 and the flat section 12a, which is a central region of the tray 1a, is set so as to take into account the temperature difference (the temperature distribution within a horizontal plane parallel to the substrate 2) with the edge regions.

In addition, a recess 13a shown in FIG. 5B that is configured such that the cross-sectional shape expands outward from the center is provided in a region that extends from the location of the radius r, which is a peripheral location of the flat section 12a, to a location directly below the side surface of the indentation 11a located above, or in other words, extends to a location directly below the edges of the substrate 2.

In other words, as shown in FIG. 5C, the recess 13a on the rear surface of the tray 1a has a ring shape when the rear surface side is viewed from the front, and the recess 13a is scooped out at an angle so as to become deeper toward the front surface side moving outward from the flat section 12a.

In addition, the recess 13a has a cross-sectional shape of two right triangles disposed symmetrically in the left-right direction with respect to the center line of the tray 1a in FIG. 5B, and the height of these right triangles is such that the greatest height “ha” is at a peripheral location of the recess 13a. The length of the peripheral location of the recess 13a from the center along the radius r is configured so as to be approximately 3.8 to 4.2 times the radius r. The recess 13a forms a gap between the tray 1a and the susceptor 7. The region from the peripheral location of the recess 13a to the periphery of the circle of the rear surface of the tray 1 is configured so as to be flat.

In other words, the tray 1a shown in FIGS. 5A to 5C differs from the tray 1 shown in FIGS. 3A to 3C in that the shape of the indentation 11a in the top surface side and the shape of the bottom surface side are different. The indentation 11a provided in the top surface side and the recess 13a provided in the bottom surface side are formed by cutting a base material made of crystal such as SiC, TaC, for example, or the like. The cutting may be performed consecutively one surface at a time, starting with the top surface and then continuing with the bottom surface, or the cutting may be performed simultaneously on both the upper and bottom surfaces. Other configurations of the tray 1a are equivalent to those of the tray 1 shown in FIGS. 3A to 3C; overlapping descriptions thereof are therefore omitted.

For the tray 1a shown in FIGS. 5A to 5C, the location of the recess 13a corresponds to the high heat energy region, and conduction of heat from the susceptor 7 in the high heat energy region to the edge regions of the indentation 11a above the recess 13a is prevented. Meanwhile, the location of the flat section 12a corresponds to the low heat energy region, and a contact region with the susceptor 7 in the central region of the indentation 11a above the flat section 12a is sufficiently ensured; thus, it is possible to reliably heat the substrate 2 even if heat flows from the susceptor 7 in the low heat energy region.

Also, as shown in FIGS. 6A to 6C, the shape of the top surface of the tray as seen from above may be substantially circular, and the tray may be a tray 1b in which an indentation 11b is formed in the center of the top surface on which the substrate 2 rests, with the bottom of the indentation 11b being an upward protrusion and the indentation 11b having a diameter than is substantially the same as the diameter of the substrate 2, for example.

As shown in the top view of FIG. 6A and the cross-sectional view of FIG. 6B, the tray has a shape in which the center of the bottom of the indentation 11b has a protrusion that protrudes; thus, similar to the indentation 11 shown in FIG. 3B, the indentation 11b is configured such that a depth d2b at the edges of the indentation 11b is deepest, the bottom of the indentation 11b protrudes upward so as to gradually rise in the left-right direction from the edges to the center, and the depth d1b at the center is the shallowest.

The depth d1b at the center of the indentation 11b can be configured so as to be approximately 0.4 mm to 3 mm, the same as for the tray 1 shown in FIGS. 3A to 3C. The contact area of the substrate 2 and the central region of the indentation 11b in the tray 1b is set so as to take into account the temperature difference (the temperature distribution within a horizontal plane parallel to the substrate 2) with the edge regions.

In addition, as shown in the bottom view of FIG. 6C, a circular flat section 12b is provided on the bottom surface side of the tray 1b in a region that extends outward from the center to the radius r. The contact area of the susceptor 7 and the flat section 12a, which is a central region of the tray 1a, is set so as to take into account the temperature difference (the temperature distribution within a horizontal plane parallel to the substrate 2) with the edge regions. A ring-shaped recess 13b that is concentric to the flat section 12b and has a bottom parallel to the surface of the flat section 12b is provided to the exterior of the peripheral locations of the flat section 12b of the bottom surface of the tray 1.

In addition, as shown in FIG. 6B, the recess 13b in the bottom surface of the tray 1b is a U-shaped groove that has a shape in cross-section of a two isosceles trapezoids in which the upper base is shorter than the lower base and the trapezoids are disposed symmetrically in the left-right direction with respect to the center line of the tray 1b. A height “hb” of the trapezoids constitutes the maximum height of the recess 13b.

The periphery of the U-shaped groove ring of the bottom of the recess 13b is disposed directly below the side surface of the indentation 11b located above the recess 13b, or in other words, in a location directly below the edge of the substrate 2. The length of a peripheral location of the ring of the bottom of the recess 13b from the center along the radius r is configured so as to be approximately 3.8 to 4.2 times the radius r. The recess 13b forms a gap between the tray 1b and the susceptor 7. The region from the peripheral location of the recess 13b to the periphery of the circular bottom surface of the tray 1 is configured so as to be flat.

In other words, the shape of the indentation 11b in the top surface side of the tray 1b shown in FIGS. 6A to 6C is fundamentally the same as that for the tray 1 shown in FIGS. 3A to 3C and is configured so as to take into account the contact area with the substrate 2. The shape of the bottom surface side differs from that for the tray 1 shown in FIGS. 3A to 3C and the tray 1a shown in FIGS. 5A to 5C. However, as was the case for the tray 1a shown in FIGS. 5A to 5C, the shape of the bottom side was configured so as to take into account the contact area with the susceptor 7. Other configurations of the tray 1b are equivalent to those of the tray 1 and the tray 1a; overlapping descriptions thereof are therefore omitted.

For the tray 1b shown in FIGS. 6A to 6C, the location of the recess 13b corresponds to the high heat energy region, and the flow of heat from the high heat energy region to the substrate 2 is prevented in the edge regions of the indentation 11b above the recess 13b. Meanwhile, the location of the flat section 12b corresponds to the low heat energy region, and a contact region with the susceptor 7 in the central region of the indentation 11b above the flat section 12b is sufficiently ensured; thus, it is possible to reliably heat the substrate 2 even if heat flows from the low heat energy region.

### Working Examples

Next, the present invention will be described by defining the epitaxial growth method that used tray 1 shown in FIGS. 3A to 3C as “Working Example 1,” the epitaxial growth method that used the tray 1a shown in FIGS. 5A to 5C as “Working Example 2,” and the epitaxial growth method that used the tray 1b shown in FIGS. 6A to 6C as “Working Example 3.”

First, the values for the various members of the respective trays in Working Examples 1 to 3 will be described. The tray 1 according to “Working Example 1” has a depth d1 of approximately 400 μm at the center of the indentation 11 shown in FIGS. 3A to 3C, and a depth d2 of approximately 430 μm at a location at the periphery of the indentation 11 that corresponds to the edge of the substrate 2.

The tray 1a according to “Working Example 2” has a depth d1a of approximately 400 μm at the center of the indentation 11a shown in FIGS. 5A to 5C. The radius r of the flat section 12a is approximately 10 mm. The maximum height “ha” of the right triangles in the cross-section of the recess 13b is approximately 2 mm. A location of the recess 13a that is directly below the edges of the substrate 2 has a length (radius) of approximately 38.5 mm from the center.

The tray 1b according to “Working Example 3” has a depth d1b of approximately 400 μm at the center of the indentation 11b shown in FIGS. 6A to 6C, and a depth d2b of approximately 450 μm at a location at the periphery of the indentation 11b that corresponds to the edge of the substrate 2. The radius r of the flat section 12b is approximately 10 mm. The maximum height “hb” of the trapezoids in the cross-section of the recess 13b is approximately 1.5 mm. A location of the recess 13b that is directly below the edges of the substrate 2 has a length (radius) of approximately 38.5 mm from the center.

Next, the epitaxial growth method for Working Examples 1 to 3 will be described in detail. First, wafers with a diameter of 3 inches (approximately 77 mm) and a thickness of approximately 350 to 400 μm were prepared as the substrates 2 for the respective Working Examples 1 to 3. The substrates 2 were 4H—SiC substrates 2 in which the Si surface was offset by 8°, and the substrates 2 were thoroughly washed using a well-known organic washing method, RCA washing, or the like. The washed substrates 2 were then arranged and fixed inside the indentations 11, 11a, 11b in the trays 1, 1a, 1b of the respective Working Examples 1 to 3.

Next, the trays 1, 1a, 1b were each arranged within a transfer chamber that was continuous with the reaction vessel 3, which was the growth chamber where epitaxial growth would be carried out on the respective substrates 2 mounted on the trays 1, 1a, 1b.

Next, after the interior of the reaction vessel 3 was pre-evacuated, the trays 1, 1a, 1b were transferred from the transfer chamber and introduced into the reaction vessel 3, and the interior of the reaction vessel 3 was evacuated to a vacuum of less than or equal to approximately 2×10⁻⁶ Pa.

During this evacuation, the transferred trays 1, 1a, 1b were arranged on susceptors 7 inside the reaction vessel 3.

Next, H₂ gas purified using a purifier was introduced into the reaction vessel 3 at a flow of approximately 30 liters/minute (0.03 m³/minute), replacing the atmosphere within the reaction vessel 3 with H₂ gas. At such time, the H₂ pressure was set to approximately 20 Torr (approximately 2.67 kPa).

After the atmosphere was replaced, the substrate 2 was heated from the bottom surface via high frequency induction while maintaining a state in which H₂ gas was introduced in a similar manner into the reaction vessel 3 at a flow of approximately 30 liters/minute (0.03 m³/minute).

During the heating process, the output of the high frequency power source 6 was first gradually increased starting at 0 W, and the temperature was caused to reach a temperature set between approximately 1550° C. and 1650° C. The temperature during the heating process was determined by monitoring the surfaces of the substrate 2 using a radiation thermometer provided in the reaction vessel 3.

After the temperature within the reactor reached the set temperature, the temperature within the reactor was maintained at the set temperature for approximately 5 minutes. By maintaining this temperature, the front surface of the SiC substrate was H₂ etched and made into a clean surface.

Thereafter, SiH₄, C₃H₈, and hydrochloric acid (HCl), which were the source material gases, were introduced into the reaction vessel 3 with the amount introduced for each gas being adjusted to the following amounts in order to simultaneously satisfy the growth conditions (1) and (2) listed below: SiH₄ gas=120 sccm (approximately 0.2 Pa·m³/s), C₃H₈ gas=44 sccm (approximately 7.4×10⁻² Pa·m³/s), and HCl gas=360 sccm (approximately 0.61 Pa·m³/s).

(1) SiH₄ and C₃H₈ concentration ratio (C/Si ratio): 1.1

(2) SiH₄ and HCl concentration ratio (Cl/Si ratio): 3.0

N₂, which was the doping gas, was introduced with the flow being adjusted such that the carrier concentration was 3×10¹⁵/cm³. At the same time, the growth temperature inside the reactor was set to approximately 1630° C. The growth rate for the thickness of a 4H—SiC film is generally several μm/hour (h) or so. In the present working examples, however, the semiconductor film 2a was epitaxially grown for approximately 18 minutes at a high speed growth rate of approximately 115 μm/h.

After growth was finished, the substrate 2 was cooled using only H₂ carrier gas as the cooling atmosphere, whereby the process for manufacturing an epitaxial substrate in which a 4H—SiC film with a thickness of approximately 33 μm at the center of the substrate 2 was carried out for the three patterns of Working Examples 1 to 3.

### Comparison Example

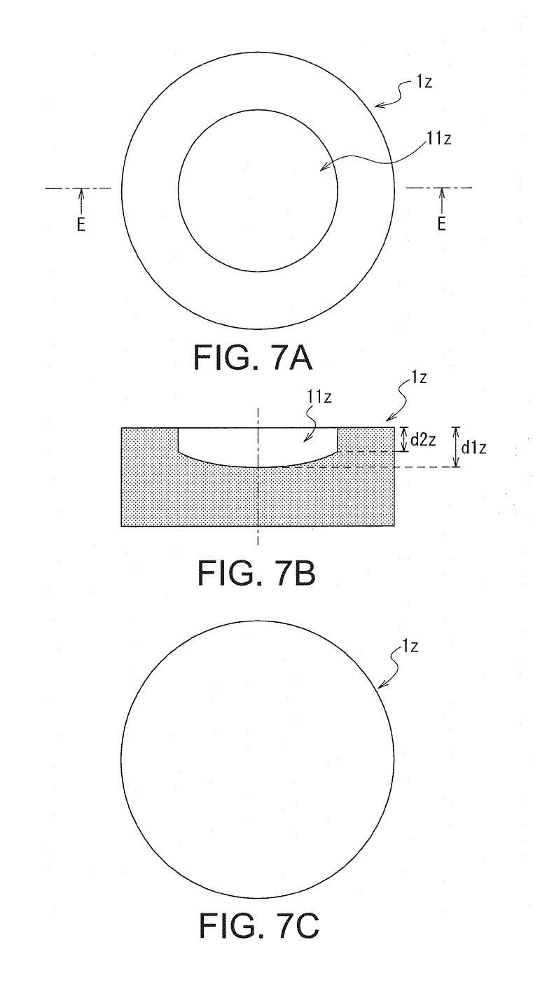

Meanwhile, a tray 1z according to a comparison example shown in FIGS. 7A to 7C was prepared. The planar shape of the tray 1z according to the comparison example was a substantially circular plate-like shape as a whole when viewed from above, and, as seen in the top view of FIG. 7A, an indentation 11z with substantially the same diameter as the diameter of the substrate 2 was formed in the center of the front surface side of the tray 1z on which the substrate 2 rested.

As shown in the cross-sectional view of FIG. 7B, the indentation 11z had a protrusion-like shape in the bottom surface direction. In other words, the bottom of the indentation 11z was configured so as to protrude downward so as to gradually grow deeper moving in the left-right direction from the edges toward the center, thereby being shallowest at the center. A depth d1z at the center of the indentation 11z was approximately 450 μm, and a depth d2z at a location at the periphery of the indentation 11z that corresponded to the edges of the substrate 2 was approximately 400 μm.

As shown in the bottom view of FIG. 7C, the bottom surface of the tray 1z according to the comparison example was flat, and no particular treatment was carried out on this bottom surface.

Treatment similar to that of the epitaxial growth method described in the above-mentioned Working Examples 1 to 3 was carried out using the tray 1z according to this comparison example, and a pattern was carried out in which an epitaxial substrate was manufactured with a 4H—SiC film with a thickness of approximately 33 μm being formed on the substrate.

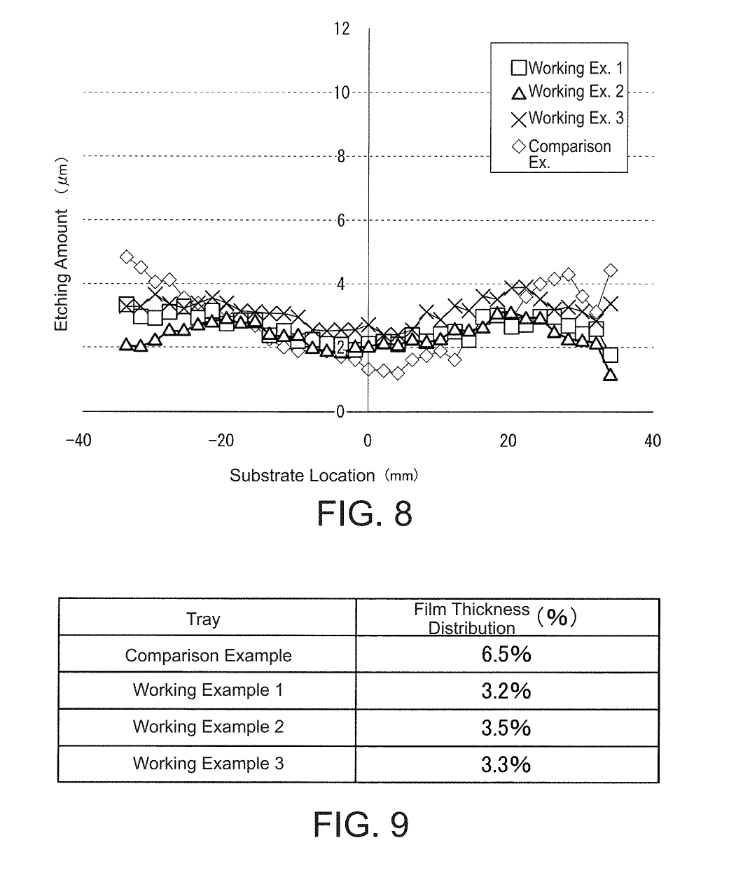

The graph in FIG. 8 shows results calculated using the four types of trays constituted of the trays 1, 1a, 1b according to Working Examples 1 to 3 and the tray 1z according to the comparison example. These results were for the distribution of the etching amount when the epitaxial substrates on which the 4H—SiC films were formed were hydrogen etched by introducing H₂ gas into a 1620° C. reaction vessel 3 at 30 liters/minute (0.03 m³/minute) for 20 minutes. In these calculations, the thickness distributions before and after etching were respectively measured using Fourier transport infrared spectroscopy (FTIR), and the calculations were made using the before-after etching difference from the measurement results.

It can be seen in FIG. 8 that in locations of the epitaxial substrate in which there was large amount of hydrogen etching the actual temperature during epitaxial growth was high. For the tray 1z according to the comparison example, which is represented by a plot of diamond (⋄) shapes in FIG. 8, the amount of etching near the center of the wafer was small, while the amount of etching at the edges of the wafer was large. Thus, it can be seen that the temperature at the edges of the wafer was higher than at the center.

Meanwhile, for the tray 1 according to “Working Example 1,” which is represented by a plot of square (□) shapes in FIG. 8, the tray 1a according to “Working Example 2,” which is represented by a plot of triangles (Δ) in FIG. 8, and the tray 1b according to “Working Example 3,” which is represented by a trajectory made by using a plot of cross (x) marks, the amount of hydrogen etching near the center of the substrate 2 was higher and the amount of etching at the edges was lower than in the comparison example. Therefore, for Working Examples 1 to 3, it can be seen that there was a tendency for temperature differences within the plane of the substrate 2 to be eliminated.

The table in FIG. 9 shows the thickness distributions (%) when the tray 1z according to the comparison example and the trays 1, 1a, 1b according to Working Examples 1 to 3 were used. These thickness distributions represent the averages for respective ratios of the difference between the thickness at various locations within the plane of the substrate 2 and the thickness at the center with respect to the thickness at the center.

The thickness distribution for the tray 1z according to the comparison example was 6.5%. The thickness distribution improved to around 3.3%, approximately half of that for the comparison example, when growth was performed using the trays 1, 1a, 1b according to Working Examples 1 to 3. For the tray 1z according to the comparison example, since the temperature near the center of the substrate 2 was lower and the temperature near the edges of the substrate 2 was higher during epitaxial growth, the amount of etching of the SiC epitaxial film was higher at the edges and the thickness was thinner compared to near the center; thus, the distribution was larger. Meanwhile, for the trays 1, 1a, 1b according to the Working Examples 1 to 3 in which the distribution of the flow of heat was improved, it can be seen that the difference between the amount of etching near the center and the amount of etching near the edges was smaller, and that there was an improvement in the thickness distribution.

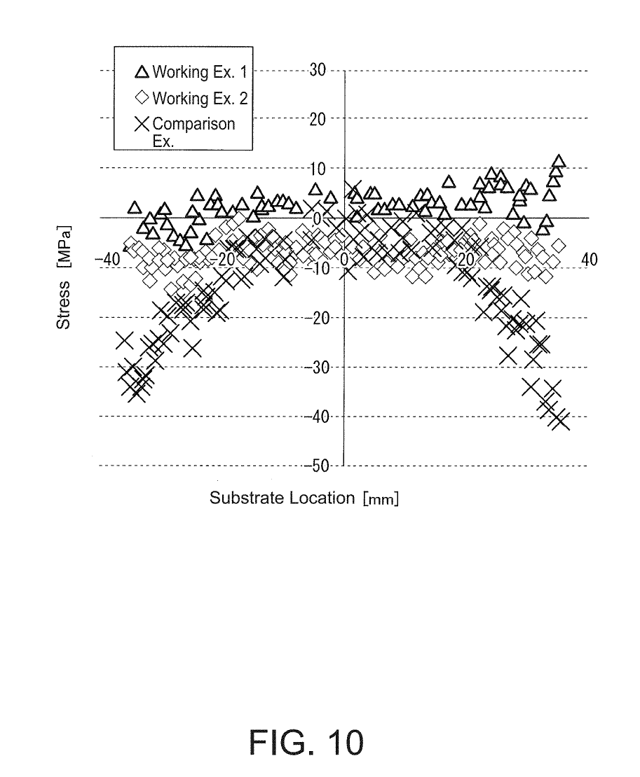

The graph in FIG. 10 shows results in which the stress of the respective 4H-SiC films was assessed using Raman spectroscopy. The stress evaluation was performed using line analysis at 1 mm intervals from one edge in the in-plane direction of the substrate 2 to the other edge on the opposite side. FIG. 10 shows a difference in which the measurement results for a substrate 2 on which a 4H—SiC film has not been epitaxially grown have been subtracted from the measurement results for a substrate 2 on which a 4H—SiC film has been epitaxially grown.

For the tray 1b according to the comparison example, which is represented by a plot of cross (x) marks in FIG. 10, a large amount of tensile stress was generated at the edges of the substrate 2. Meanwhile, the stress distribution is substantially flat when using the tray 1 according to “Working Example 1” that is represented by a plot of triangle (Δ) shapes in FIG. 10 and the tray 1a according to “Working Example 2” that is represented by a plot of diamond (⋄) shapes in FIG. 10. It can be seen that, since the temperature distribution was improved, there was a decrease in the amount of stress generated by thermal strain.

The images in FIGS. 11A to 11C are pictures that captured interface dislocations using radiation topography of the 4H—SiC films grown by using the tray 1z according to the comparison example, the tray 1 according to “Working Example 1,” and the tray 1a according to “Working Example 2.” FIG. 11A is an image of a region of the 4H-Sic film according to the comparison example in which the region was centered on a location at a radius of 30 mm from the center of the substrate 2 in which there was significant occurrence of interface dislocation.

FIG. 11B is an image of a region of the 4H—SiC film of “Working Example 1” that corresponds to the region captured for the comparison example. FIG. 11C is an image of a region of the 4H—SiC film according to “Working Example 2” that corresponds to the region captured for the comparison example.

As shown in FIG. 11A, a large amount of interface dislocation occurred when epitaxial growth was performed using the tray 1z according to the comparison example. Meanwhile, as shown in FIG. 11C, it can be seen that no interface dislocation is evident and there is a large improvement in the quality of the 4H—SiC film when epitaxial growth is performed using the tray 1 according to “Working Example 1” and the tray 1b according to “Working Example 2.”

As described above, when 4H—SiC films are epitaxially grown using the trays 1, 1a, 1b according to Working Examples 1 to 3, it is possible to improve the thickness distribution and reduce the thickness distribution and film stress. As a result of preventing the occurrence of stress, it is possible to greatly reduce dislocation that occurs at the interface of the 4H—SiC film with the substrate 2.

<Manufacturing Method of Semiconductor Element>

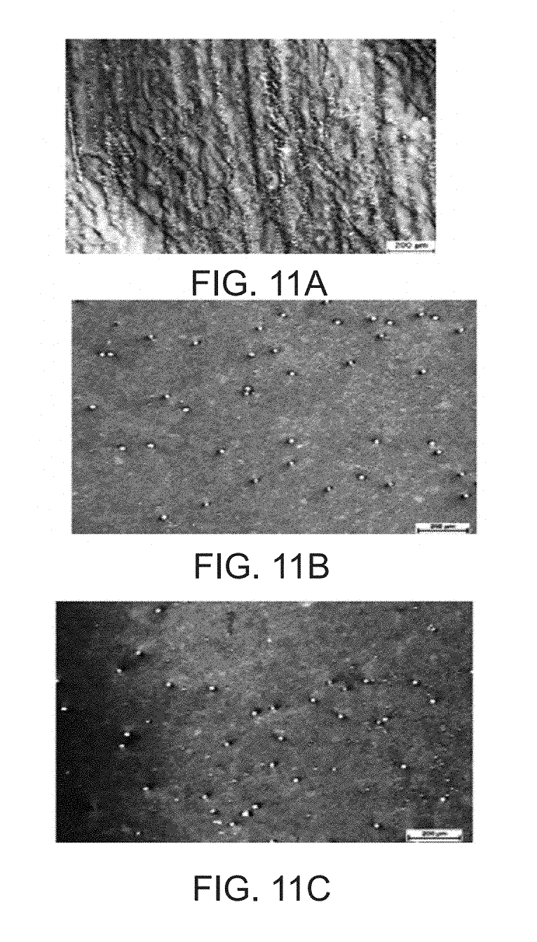

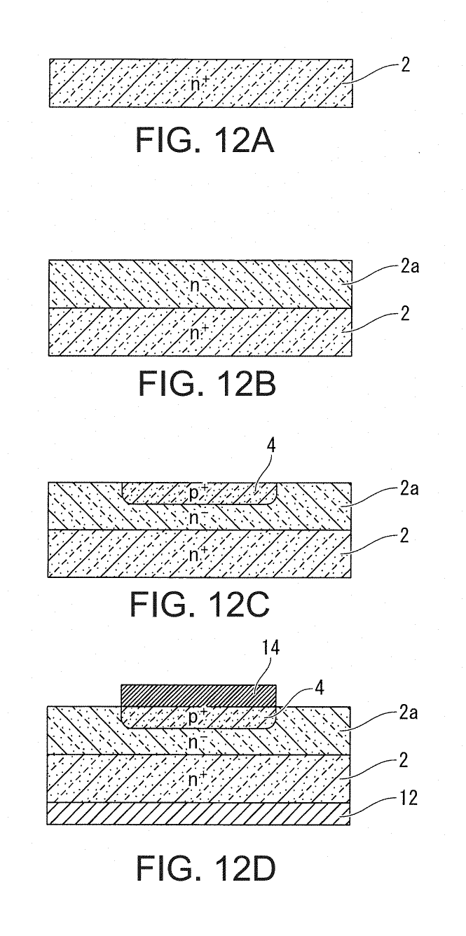

Next, a manufacturing method of a semiconductor element that utilizes an epitaxial substrate on which a 4H—SiC film has been formed using the epitaxial growth method according to an embodiment of the present invention will be explained with reference to FIGS. 12A to 12D.

First, as shown in FIG. 12A, an n⁺4H—SiC substrate 2 is prepared, and the prepared substrate 2 is housed in an indentation 11 in which the thickness toward the center of the substrate 2 is larger than a thickness toward the edges of the substrate 2 as measured from the bottom of the indentation 11 to the bottom surface of the tray 1. Next, an n⁻4H—SiC semiconductor film 2a is epitaxially grown on the substrate 2 using the above-described epitaxial growth method, and, as shown in FIG. 12B, a 4H—SiC film that constitutes a first semiconductor region is formed.

Next, as shown in FIG. 12C, impurity element ions such as aluminum (Al), for example, are implanted inside the first semiconductor region using ion implantation, forming a p⁺ second semiconductor region 4.

Next, as shown in FIG. 12D, an ohmic contact anode electrode film 14 such as a stacked film of nickel (Ni), titanium (Ti), and Al, for example, is bonded and formed on the second semiconductor region 4. A cathode electrode film 12 made of Ni, for example, is formed on the rear surface of the substrate 2. Thereafter, a prescribed vacuum annealing process is performed, completing the manufacturing method of the semiconductor element according to an embodiment of the present invention.

By appropriately modifying and combining the type of introduced impurity elements, the concentrations of the respective impurity elements, and the introduction methods thereof, it is possible to manufacture various types of semiconductor elements. For example, an example was shown in FIGS. 12A to 12D of a semiconductor element having a p-n junction, but is possible to manufacture other types of semiconductor elements, such as a semiconductor element in which an n⁺ second semiconductor region that has a higher concentration than an n⁻ first semiconductor region is formed as a contact region.

According to a manufacturing method of a semiconductor element according to an embodiment of the present invention, by controlling the temperature distribution in the radial direction of the substrate 2 during epitaxial growth, it is possible to use an epitaxial substrate that controls thickness distribution, prevents the occurrence of defect dislocation, and reduces warping (stress) of the substrate 2; thus, it is possible to manufacture various types of semiconductor elements such as an SBD, a MOSFET, a superjunction MOSFET (SJMOS), an IGBT, or the like while improving device characteristics.

In addition, since warping of the substrate 2 is reduced, it possible to improve the manufacturing precision during the manufacturing process of the semiconductor element, and it is possible to also improve the yield.

### Other Embodiments

The present invention was described using the above-disclosed embodiments and working examples, but the description and drawings constituting a portion of the disclosure do not limit the invention. Various substitute embodiments, working examples, and applied techniques should be clear to a person skilled in the art based on this disclosure.

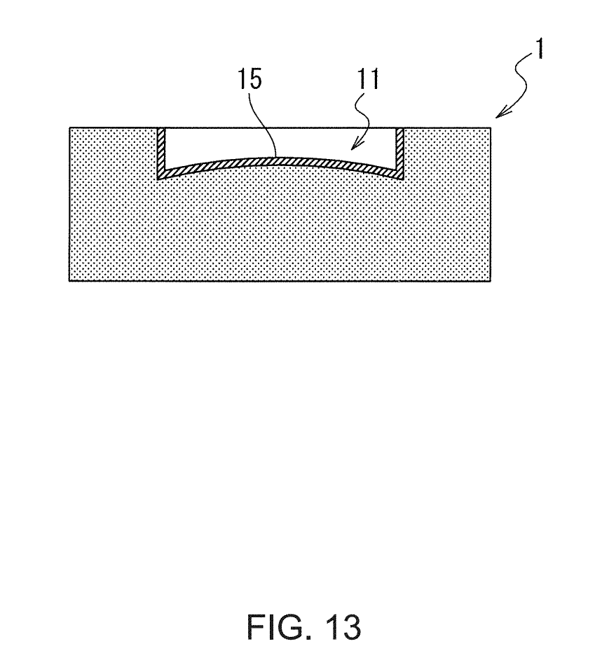

As shown in the cross-sectional view of FIG. 13, it is possible to improve the contact between the tray and the substrate 2 by forming a tray 1 in which a coating layer 15 made of TaC or SiC is provided on the bottom and the side surfaces of the indentation 11, for example.

In addition, the trays 1, 1a, 1b shown in FIGS. 3A to 6C each had a circular plate-like shape when viewed from above. The shape of the tray is not limited to this, however, and the bottom may be configured to have a different shape, such as a rectangle, for example. In addition, the invention is not limited to placing one substrate 2 on one tray, and a shape having a dimension in which a plurality of two or more substrates 2 are mounted may also be used.

In addition, the epitaxial growth apparatus is not limited to a high frequency induction heating-type film formation apparatus, as long as the apparatus is able to promote epitaxial growth by increasing the temperature of the SiC semiconductor film 2a to the necessary film formation temperature. If the growth apparatus has a configuration in which the amount of conduction heat transmitted to the central region of the substrate 2 within a plane parallel to the main surface of the substrate 2 is lower than the amount transmitted to the edges and a biased temperature distribution occurs in the susceptor 7 located below the tray 1, the growth apparatus may be a film formation apparatus that uses a different type of heating method such as infrared lamp heating.

The present invention as described above includes various embodiments and the like not disclosed above, and the technical scope of the present invention is limited only by features of the invention according to the claims that are appropriate based on the description above. It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention

What is claimed is:

1. An epitaxial growth apparatus, comprising:
a reaction vessel where a semiconductor film made of silicon carbide is epitaxially grown on a substrate;
a tray having a top surface, a bottom surface, and an indentation in the top surface that houses said substrate, a thickness of the tray near a center of the indentation being greater than a thickness of the tray near an edge of the indentation as measured from a bottom of the indentation to the bottom surface of the tray; and
a support plate inside the reaction vessel that mounts the tray thereon so as to thermally contact the tray, thereby heating the tray.

2. The epitaxial growth apparatus according to claim 1, wherein said indentation in the tray has a protruding section that partially contacts a bottom of the substrate at the center of the indentation so as to achieve said distribution in thickness of the tray near the center of the indention and said thickness of the tray near the edge of the indentation.

3. The epitaxial growth apparatus according to claim 1, wherein the tray has a recess provided in the bottom surface of the tray so as to achieve said distribution in thickness of the tray near the center of the indention and said thickness of the tray near the edge of the indentation.

4. The epitaxial growth apparatus according to claim 2, wherein the tray is made of carbon.

5. The epitaxial growth apparatus according to claim 4, further comprising a carbide coating layer provided on the top surface of the tray.

6. A method of epitaxial growth, comprising:
preparing a tray having an indentation provided in a top surface of the tray, a thickness of the tray near a center of the indentation being thicker than a thickness of the tray near an edge of the indentation as measured from a bottom of the indentation to a bottom surface of the tray;
housing a substrate in the indentation in the tray;
placing the tray inside a reaction vessel and mounting the tray on a support plate; and
increasing a temperature of the substrate by heating the substrate via the support plate and the tray so as to epitaxially grow a semiconductor film made of silicon carbide on the substrate.

7. A method of manufacturing a semiconductor element, the method comprising:
preparing a tray having an indentation provided in a top surface of the tray, a thickness of the tray near a center of the indentation being thicker than a thickness of the tray near an edge of the indentation as measured from a bottom of the indentation to a bottom surface of the tray;
housing a substrate in the indentation in the tray;
placing the tray inside a reaction vessel and mounting the tray on a support plate;
forming a first semiconductor region by increasing a temperature of the substrate by heating the substrate via the support plate and the tray so as to epitaxially grow a semiconductor film made of silicon carbide on the substrate; and
forming a second semiconductor region by introducing an impurity element into a top of the first semiconductor region.
